(19) United States
(12) Patent Application Publication
(10) Pub. No.: US 2006/0197216 A1
(43) Pub. Date: Sep. 7, 2006

(54) Semiconductor package structure and method for manufacturing the same

(75) Inventor: Kuo Chung Yee, Taipei (TW)

Correspondence Address: LOWE HAUPTMAN BERNER, LLP, 1700 DIAGONAL ROAD, SUITE 300, ALEXANDRIA, VA, 22314, US

(73) Assignee: ADVANCED SEMICONDUCTOR ENGINEERING, INC., Kaohsiung (TW)

(21) Appl. No.: 11/294,598

(22) Filed: Dec. 6, 2005

(30) Foreign Application Priority Data
Mar. 2, 2005 (TW) 094106298

(51) Int. Cl. H01L 23/12

(52) U.S. Cl. 257/704

(57) ABSTRACT

A semiconductor package structure comprises a chip, a plurality of via holes, a lid, an adhesive ring and a plurality of metal traces, wherein the chip has an optical component and a plurality of pads disposed on its active surfaces; the via holes penetrate the chip and are electrically connected to the pads; the lid is adhered onto the active surface of the chip by the adhesive ring such that the adhesive ring surrounds the optical component; and the plurality of metal traces is disposed on the back surface of the chip, electrically connected to the plurality of via holes, and used to define a plurality of solder pads thereon. The present invention also provides a method for manufacturing the semiconductor package structure.

### CROSS REFERENCE TO RELATED APPLICATION

This application claims the priority benefit of Taiwan Patent Application Serial Number 094106298, filed on Mar. 2, 2005, the full disclosure of which is incorporated herein by reference.

### BACKGROUND OF THE INVENTION

1. Field of the Invention

This invention generally relates to a semiconductor package structure and a method for manufacturing the same, and more particularly to a wafer level semiconductor package structure and a method for manufacturing the same.

2. Description of the Related Art

The semiconductor package mainly serves four functions, i.e. signal distribution, power distribution, heat dissipation and element protection. In general, a semiconductor chip is packaged into an enclosure, and then disposed on a printed circuit board, together with other components, such as capacitors, resistors, inductors, filters, switches, and optical and RF components.

The complementary metal-oxide semiconductor (CMOS) technology for making optical components is similar to that for making semiconductor chips. CMOS is typically formed from silicon (Si) and germanium (Ge) and generally includes N-type metal-oxide semiconductor (NMOS) transistors with negative charged carriers and P-type metal-oxide semiconductor (PMOS) transistors with positive charged carriers. Such NMOS and PMOS may generate currents after sensing light, and the currents may be then recorded and read as image.

Further, as the demands for lighter and more complex electronic devices gradually increase, the operating speed and the complexity of IC chips have become higher and higher. Accordingly, a higher packaging efficiency is required. In the prior art, various semiconductor packages and manufacturing methods have been provided for improving the packaging efficiency and reliability. For example, U.S. Pat. No. 6,040,235 entitled “Methods And Apparatus For Producing Integrated Circuit Devices” issued to Badehi on May 21, 2000, and U.S. Pat. No. 6,117,707 entitled “Methods Of Producing Integrated Circuit Devices” issued to Badehi on Sep. 12, 2000 disclose methods for manufacturing the semiconductor package structures. However, these semiconductor package structures and the manufacturing methods in the prior art still have many limitations and drawbacks, and therefore can not entirely meet the requirements for the semiconductor package structures.

Accordingly, there exists a need for providing a wafer level semiconductor package to further meet the requirement for the semiconductor package structures.

### SUMMARY OF THE INVENTION

It is an object of the present invention to provide a semiconductor package structure and a method for manufacturing the same, which can offer higher packaging efficiency and eliminate many limitations and drawbacks in the prior art.

In order to achieve the object, the present invention provides a semiconductor package structure comprising a chip, a plurality of via holes, a lid, a adhesive ring and a plurality of metal traces, wherein the chip has an optical component and a plurality of pads disposed on its active surfaces; the via holes penetrate the chip and are electrically connected to the bonding pads; the lid is adhered onto the active surface of the chip by the adhesive ring so that the adhesive ring surrounds the optical component; and the plurality of metal traces is disposed on the back surface of the chip, electrically connected to the plurality of via holes, and used to define a plurality of solder pads thereon.

The semiconductor package structure according to the present invention can be massively produced at the wafer level, thus reducing the cost for the package process and increasing the packaging reliability.

On the other hand, the present invention provides a method for manufacturing a semiconductor package structure, wherein the method comprises the following steps: providing a wafer, which defines an active surface and a back surface, and has a plurality of chips and a plurality of scribe lines positioned among the chips, wherein each chip has a plurality of bonding pads and an optical component disposed on the active surface thereof with the optical component being electrically connected to the chip; then forming a plurality of holes on the active surface of the wafer; subsequently forming conducting material within the plurality of holes, so as to form a plurality of via holes electrically connected to the plurality of bonding pads; subsequently forming on the active surface of the wafer a plurality of adhesive rings, which respectively surround the optical component of each chip; then providing a lid to be adhered to the wafer by the adhesive ring; and forming on the back surface of the wafer a plurality of metal traces, which are electrically connected to the plurality of via holes and define a plurality of soldering pads; and finally, cutting the wafer so as to form the respective semiconductor package structures.

In the method for manufacturing a semiconductor package structure of an alternative embodiment of the present invention, the plurality of adhesive rings may form on the lid so that the lid may be as well adhered onto the active surface of the wafer by the plurality of adhesive rings, thus achieving the same purpose.

The adhesive rings according to the present are formed from an adhesive material that has been mixed with a plurality of supporting units, wherein the plurality of supporting units has substantially the same height, for supporting the lid on the active surface of the wafer (chip).

The semiconductor package structure and the method for manufacturing the same according to the present invention may facilitate the transmission characteristic of the light in the semiconductor package structure owing to the fact that the lid is fixed and supported on the active surface of the chip by the adhesive ring thus rendering the optical component covered by no adhesive.

Other objects, features and advantages of the present invention as well as what have been set forth above will become more apparent from the following detailed description taking embodiments of the prevention in conjunction with the accompanying drawings.

### BRIEF DESCRIPTION OF THE DRAWINGS

FIG. 1 shows a sectional view of a semiconductor package structure according to a first embodiment of the present invention.

FIG. 2 shows a top view of the adhesive ring on the chip in a semiconductor package structure according to the first embodiment of the present invention.

FIGS. 3-17 are views used to describe the manufacturing method of a semiconductor package structure according to one embodiment of the present invention.

FIG. 18 shows a sectional view of a semiconductor package structure according to an alternative embodiment of the present invention.

### DETAILED DESCRIPTION OF THE PREFERRED EMBODIMENT

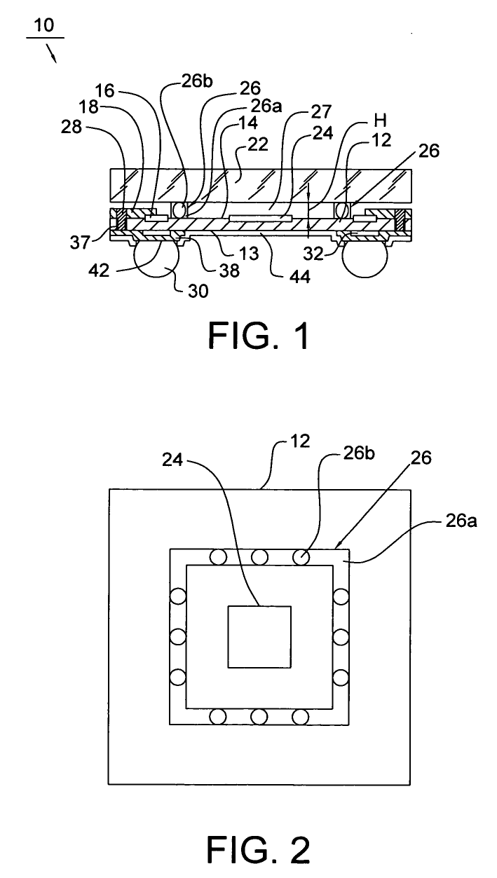

Now referring to FIG. 1, it shows a sectional view of a semiconductor package structure 10 according to a first embodiment of the present invention. The semiconductor package structure 10 comprises a chip 12 having an active surface 14, a back surface 13 opposite to the active surface 14, an optical component 24 (e.g. a sensor or a photo coupler) disposed on the active surface 14 and electrically connected to the chip 12, and a plurality of bonding pads 16 disposed on the active surface 14. The optical component 24 can be formed from complementary metal-oxide semiconductor (CMOS).

The chip 12 further has a plurality of via holes 28 penetrating the chip 12 and a plurality of pad extension traces 18 for electrically connecting the bonding pads 16 to the via holes 28. The semiconductor package structure 10 further comprises a lid 22 adhered onto the active surface 14 of the chip 12 by an adhesive ring 26, and covering the active surface 14 and the plurality of pad extension traces 18.

The semiconductor package structure 10 further comprises a plurality of compliant pads 32, a plurality of metal traces 38, a solder mask 44 and a plurality of solder balls 30. The compliant pads 32 are formed on the back surface 13 of the chip 12. The metal traces 38 are formed on the back surface 13 of the chip 12 and on the compliant pads 32. The solder mask 44 is coated on the back surface 13 of the chip 12 with parts of the metal traces 38 exposed therefrom, wherein the parts are defined as a plurality of solder pads 42. The solder balls 30 are disposed on the solder pads 42 for being connected to an external circuit, e.g. a printed circuit board. The compliant pads 32 may be formed substantially from a photosensitive benzocyclobutene polymer for reducing the internal stress or thermal stress of the semiconductor package structure 10. Further, the solder mask 44 may be formed substantially from the photosensitive benzocyclobutene polymer. The via holes 28 are electrically connected to the pad extension traces 18 and the metal traces 38, respectively, and have parts of their internal surface coated with an insulating layer 37.

Now refer to FIG. 2, where a method for manufacturing the semiconductor package structure 10 according to present invention is illustrated. The adhesive ring 26 is made of an adhesive material 26a that has been mixed with a plurality of supporting units 26b, and surrounds the optical component 24 for adhering the lid 22 onto the active surface 14 of the chip 12. In this embodiment, the plurality of supporting units 26b are substantially ball-shaped and have substantially the same diameter (or height) H, for being used to adhere the lid 22 onto the active surface 14 of the chip 12 so that a gap is present between the chip 12 and the adhesive ring 26. Also, the lid 22, the chip 12 and the adhesive ring 26 define a hermetical chamber 27 thereamong, for accommodating the optical component 24.

The lid 22 may be made of transparent material, such as glass, acrylic resin or sapphire, so that light can be transmitted through the lid 22 and interact with the optical component 24 of the semiconductor chip 12. Also, due to the fact that the lid 22 is fixed and supported on the active surface 14 of the chip 12 by the adhesive ring 26, the optical component 24 is not covered by any adhesive, thus facilitating promotion of the transmission characteristic of the light in the semiconductor package structure. Further, contamination form the environment outside can be prevented owing that the optical component 24 is located in the hermetical chamber 27.

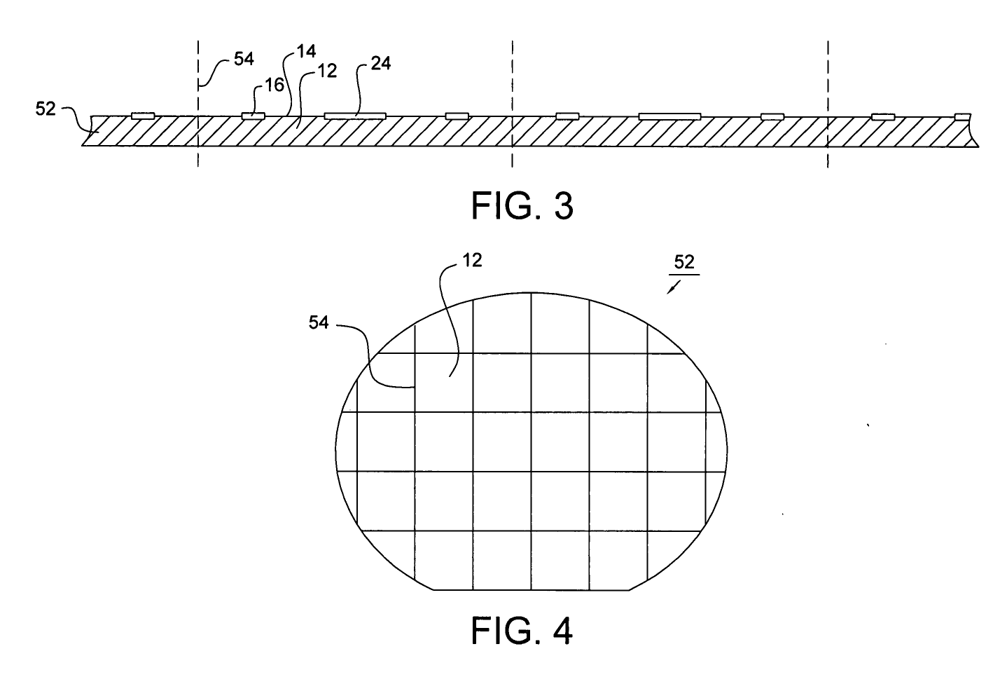

Now refer to FIGS. 3-17, which are used to depict the manufacturing method of a semiconductor package structure 10 according to one embodiment of the present invention.

As shown in FIGS. 3 and 4, a wafer 52 includes a plurality of chips 12 on which a plurality of bonding pads 16 and an optical component 24 are located, wherein adjacent chips 12 are spaced with scribe lines 54. The optical component 24 is disposed on the active surface 14, for interacting with the incident light or emitting light.

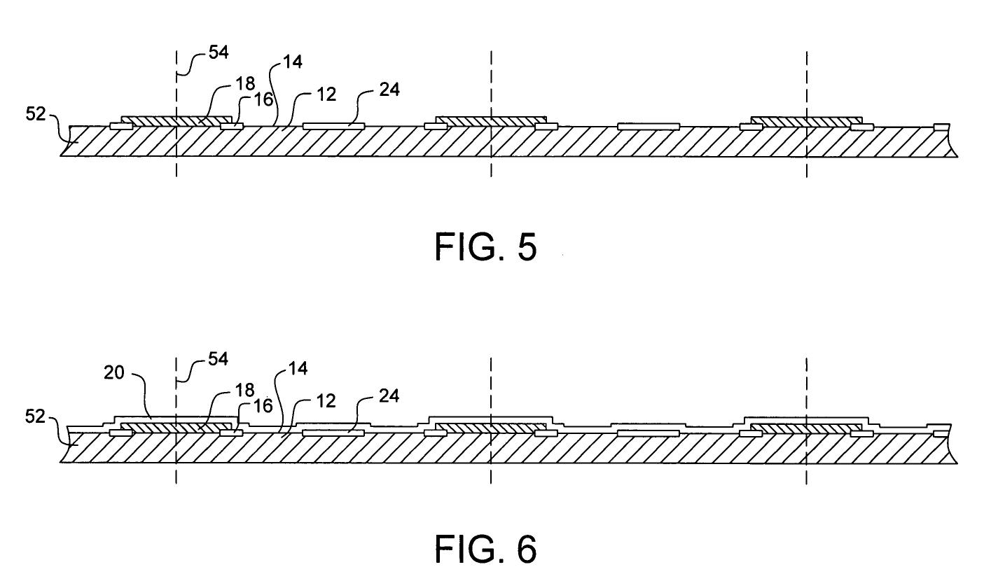

Referring to FIG. 5, a plurality of pad extension traces 18 that are electrically connected to the bonding pads 16 are formed on the wafer 52 by a photolithography and etching processes for a redistribution layer (RDL).

Referring to FIG. 6, a photoresist 20 can be optionally coated on the active surface 14 of the chip 12 so as to prevent contamination caused by drilling in a next process. It should be understood by those skilled in the art that the step of coating the photoresist 20 is optional and not absolutely necessary.

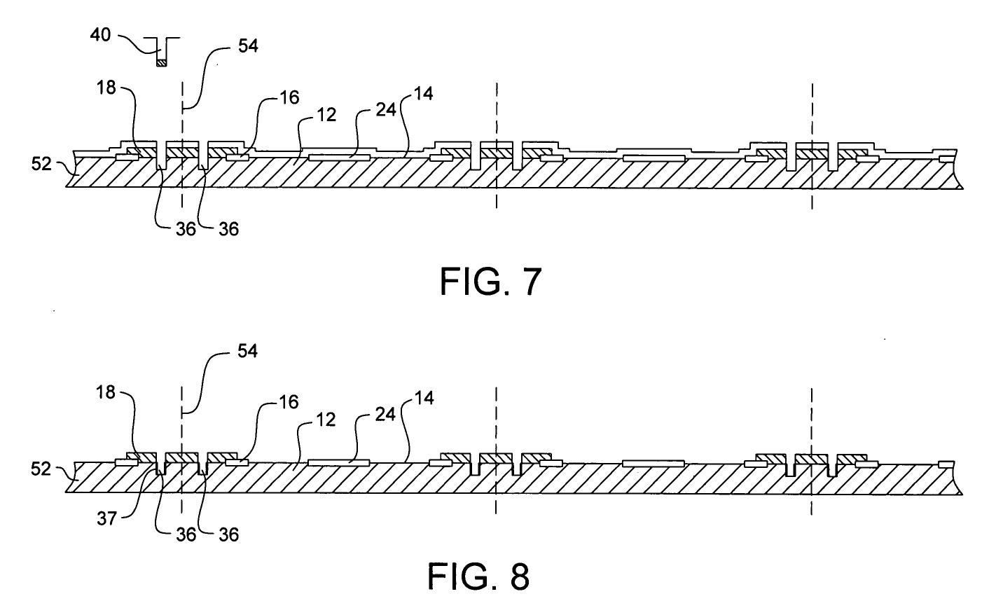

Referring to FIG. 7, a plurality of holes 36 are formed on the active surface 14 of the chip 12 by using a laser drill 40, wherein the holes have a predetermined depth that penetrates the photoresist 20 and the pad extension traces 18.

Referring to FIG. 8, the photoresist 20 is striped off and an insulating layer 37 is then formed on the inner surface of each hole 36 with at least part of the pad extension trace 18 exposed therefrom.

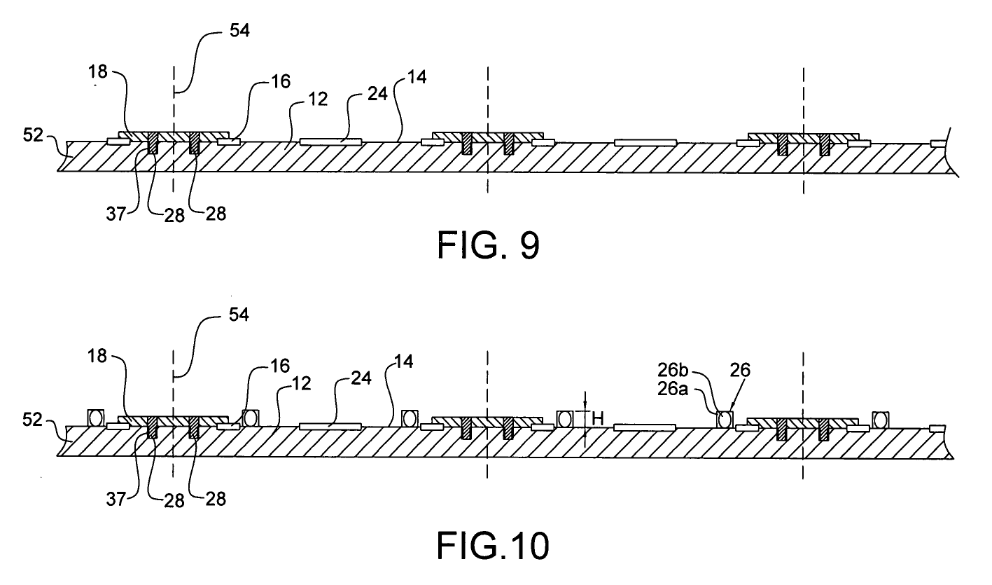

Referring to FIG. 9, a conductive material such as copper (Cu) is deposited in the plurality of holes 36 by photomasking and sputtering processes so as to form a plurality of via holes 28 that are electrically connected to the pad extension traces 18. Alternatively, the conductive material may be plated only on the inner surface of each hole 36, i.e., on part of the side surface of the insulating layer 37 and the pad extension trace 18 within each hole 36, so as to form the via holes 28 that are electrically connected to the pad extension traces 18.

Referring to FIG. 10, a plurality of adhesive rings 26 are respectively formed on the active surface 26 of each chip 12, and surround the optical component 24 on the active surface 14, as shown in FIG. 2. The adhesive ring 26 is made of an adhesive material 26a that has been mixed with a plurality of supporting units 26b, wherein the plurality of supporting units 26b are substantially ball-shaped and have substantially the same diameter (or height) H.

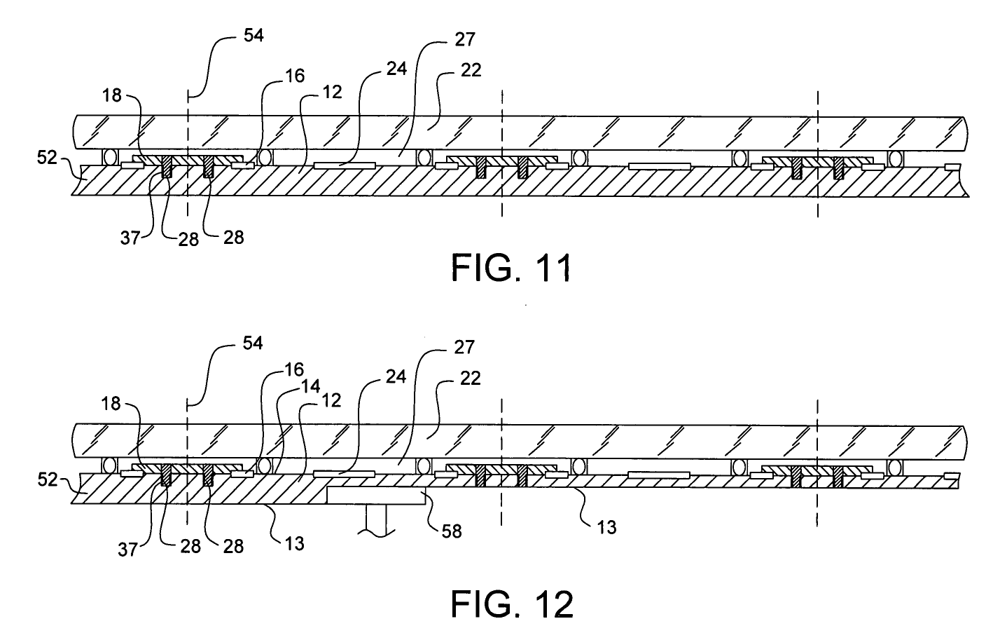

Referring to FIG. 11, a lid 22 is adhered to the wafer 52 by a plurality of adhesive rings 26 and covers the active surface 14 of the chip 12. The lid 22 can be fixed and supported on the active surface 14 of the chip 12 because the supporting units 26b of the plurality of adhesive rings 26 have substantially the same diameter (or height) H. Further, after the lid 22 has been adhered onto the wafer 52, the lid 22, the chip 12 and the adhesive ring 26 define a hermetical chamber 27 thereamong, for accommodating the optical component 24.

In one embodiment of the present invention, the plurality of adhesive rings 26 may pre-formed on the lid 22 so as to correspond to each chip 12 on the wafer 52, and then be adhered onto the active surface 14 of the each chip 12 so as to form a structure as shown in FIG. 11.

Referring to FIG. 12, the back surface 13 of the wafer 52 is ground by a mechanical grinding wheel 58 or by the chemical grinding process so as to reduce the thickness of the wafer 52 to a predetermined thickness and make the via holes 28 exposed out of the back surface 13 of the chip 12.

In one alternative embodiment of the present invention, the plurality of holes 36 may directly penetrate the chip 12 such that the subsequently formed via holes 28 are directly exposed out of the back surface 13. It could be understood by those skilled in the art that the wafer 52 may be formed to have a predetermined height without further grinding, or alternatively be ground to a predetermined thickness after forming the via holes 28.

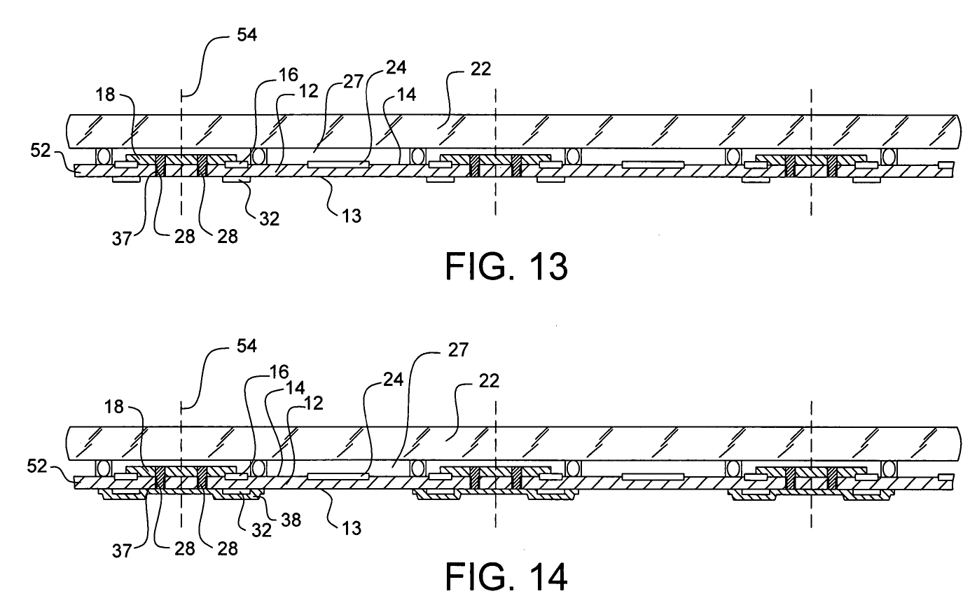

Referring to FIG. 13, a plurality of compliant pads 32 is formed on the back surface 13 of the chip 12 by a thin-film deposition process and photolithography and etching processes. The compliant pads 32 may be made of photosensitive benzocyclobutene (BCB) polymer.

Referring to FIG. 14, a plurality of metal traces 38 are formed on the back surface 13 of the chip 12 and the plurality of compliant pads 32 by a thin-film deposition process and photolithography and etching processes, wherein the metal traces 38 are respectively connected to the via holes 28.

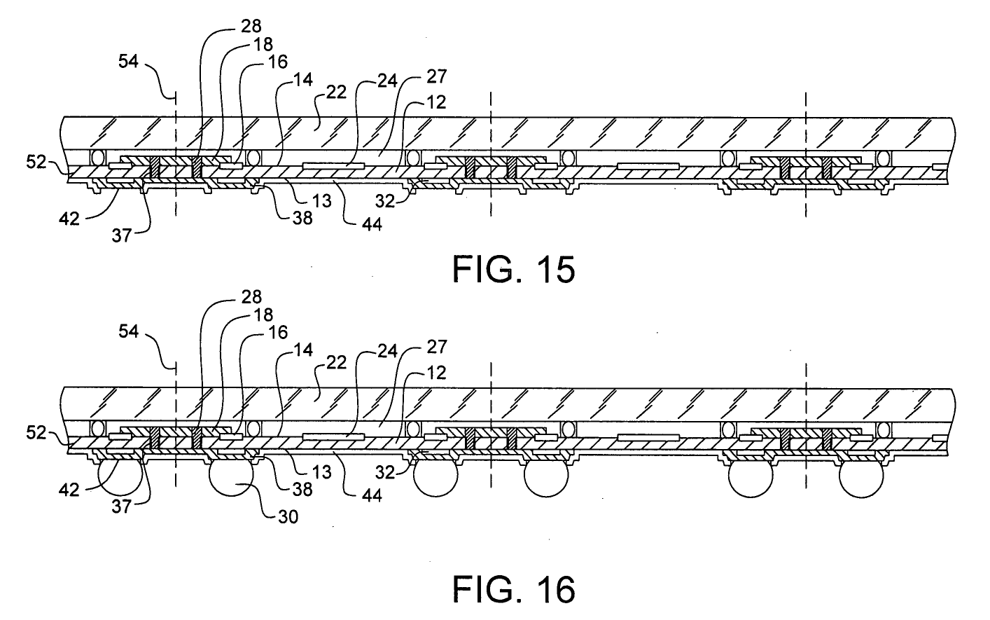

Referring to FIG. 15, a solder mask 44 is coated on the back surface 13 of the wafer 52 with parts of the metal traces 38 exposed therefrom, such that the parts can be defined as a plurality of solder pads 42 corresponding to the compliant pads 32. The solder mask 44 may be formed from photosensitive benzocyclobutene polymer.

Referring to FIG. 16, a plurality of solder balls 30 is respectively disposed on the solder pads 42.

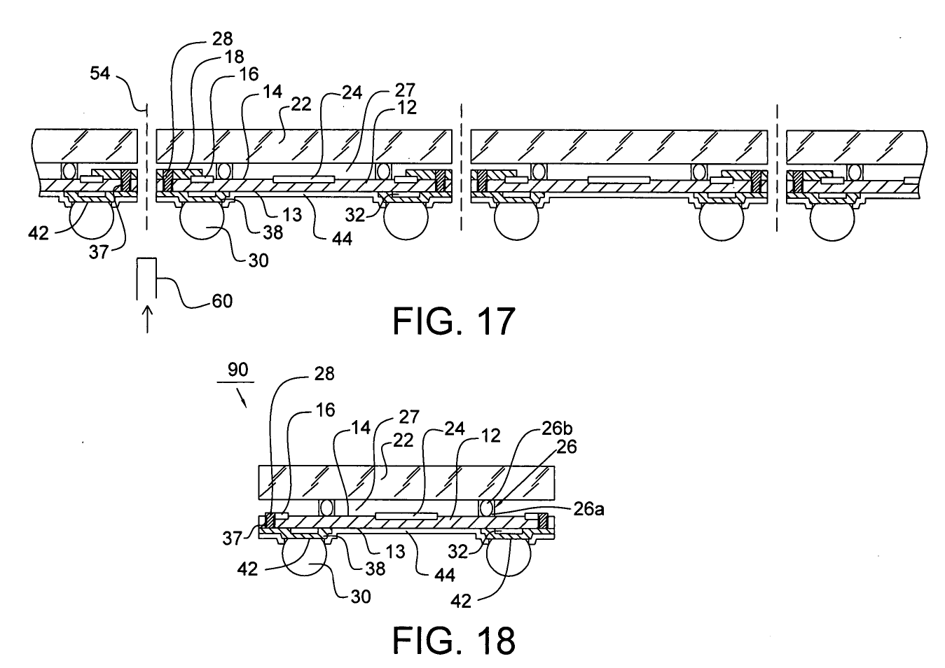

Referring to FIG. 17, a cutting blade 60 cuts the back surface 13 of the wafer 52 along predetermined paths, i.e., the scribe lines 54 of the wafer 52, for forming the semiconductor package structure 10, as shown in FIG. 1.

Now referring to FIG. 18, which shows a semiconductor package structure 90 of one alternative embodiment according to the present invention. The semiconductor package structure 90 is substantially similar to the semiconductor package structure 10, and its similar elements will be indicated by the same numerals. In the semiconductor package structure 90, the via holes 28 are formed on the bonding pads 16, and connected to the bonding pads 16.

In the semiconductor package structure and the method for manufacturing the same according to the present invention, due to the fact that the lid 22 is fixed and supported on the active surface 14 of the chip 12 by the adhesive ring 26, the optical component 24 is not covered by any adhesive, thus facilitating promotion of the transmission characteristic of the light in the semiconductor package structure 10. Further, contamination form the environment outside can be prevented owing that the optical component 24 is located in the hermetical chamber 27 defined among the lid 22, the chip 12 and the adhesive ring 25.

On the other hand, the semiconductor package structure 10, 90 are capable of being applied to the package of optical components and massively produced at the wafer level, thus reducing the cost for the package process and increasing the packaging reliability.

Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is:

1. A semiconductor package structure comprising:
a chip having an active surface, a back surface opposite to the active surface, a plurality of bonding pads disposed on the active surface, and an optical component disposed on the active surface and electrically connected to the chip;
a plurality of via holes penetrating the chip and electrically connected to the plurality of bonding pads;
a lid located on the active surface of the chip, wherein the chip, the lid and the adhesive ring define a hermetical chamber thereamong, for accommodating the optical component;
an adhesive ring being disposed between the chip and the lid and surrounding the optical component, for adhering the lid onto the active surface of the chip; and
a plurality of metal traces being disposed on the back surface of the chip, electrically connected to the plurality of via holes, and defining a plurality of solder pads thereon.

2. The semiconductor package structure as claimed in claim 1, wherein the adhesive ring is made of an adhesive material mixed with a plurality of supporting units, which have substantially the same height.

3. The semiconductor package structure as claimed in claim 2, wherein the plurality of supporting units are ball-shaped and have substantially the same diameter.

4. The semiconductor package structure as claimed in claim 1, further comprising a plurality of pad extension traces for connecting the via holes to the bonding pads.

5. The semiconductor package structure as claimed in claim 1, further comprising a plurality of compliant pads disposed between the back surface of the chip and the metal traces and corresponding to the solder pads.

6. The semiconductor package structure as claimed in claim 1, further comprising a solder mask, which covers the back surface of the chip and the metal traces with the solder pads exposed therefrom.

7. The semiconductor package structure as claimed in claim 1, further comprising a plurality of solder balls respectively disposed on the solder pads.

8. The semiconductor package structure as claimed in claim 1, wherein the lid is made of transparent material.

9. The semiconductor package structure as claimed in claim 8, wherein the transparent material is selected form a group consisting of glass, acrylic resin and sapphire.

10. A method for manufacturing a semiconductor package structure comprising the following steps:
providing a wafer that defines an active surface and a back surface opposite to the active surface and has a plurality of chips and a plurality of scribe lines formed among the chips, wherein each chip has a plurality of bonding pads and an optical component disposed on the active surface, with the optical component being electrically connected to the chip;
forming a plurality of holes on the active surface of the wafer;
forming a conductive material within the plurality of holes to form a plurality of via holes electrically connected to the bonding pads;
providing a lid to be adhered to the active surface of the wafer by a adhesive ring, wherein the chip, the lid and the adhesive ring define a hermetical chamber thereamong, for accommodating the optical component;
forming an insulating layer on the inner surface of each hole;
forming a plurality of metal traces on the back surface of the wafer, wherein the metal traces are electrically connected to the via holes and define a plurality of solder pads thereon; and
cutting the wafer to form the respective semiconductor package structures.

11. The method for manufacturing a semiconductor package structure as claimed in claim 10, further comprising the following step:
forming a plurality of adhesive rings on the active surface of the wafer, the adhesive rings respectively surrounding the optical component of each chip.

12. The method for manufacturing a semiconductor package structure as claimed in claim 10, further comprising the following step:
forming a plurality of pad extension traces on the active surface of the wafer before the step of forming the plurality of holes, the pad extension traces being electrically connected to the bonding pads, respectively; wherein the via holes are connected to the bonding pads by the pad extension traces.

13. The method for manufacturing a semiconductor package structure as claimed in claim 12, wherein the holes are formed on the pad extension traces.

14. The method for manufacturing a semiconductor package structure as claimed in claim 10, wherein the holes are formed on the bonding pads.

15. The method for manufacturing a semiconductor package structure as claimed in claim 10, further comprising the following steps:
coating a photoresist on the active surface of the chip and the bonding pads before the step of forming the holes; and
stripping off the photoresist after the step of forming the holes.

16. The method for manufacturing a semiconductor package structure as claimed in claim 10, further comprising the following step:
grinding the back surface of the wafer so as to reduce the thickness of the wafer to a predetermined thickness and make the via holes exposed out of the back surface.

17. The method for manufacturing a semiconductor package structure as claimed in claim 10, further comprising the following step:
forming a plurality of compliant pads on the back surface of the chip, corresponding to the solder pads.

18. The method for manufacturing a semiconductor package structure as claimed in claim 10, further comprising the following step:
coating a solder mask on the back surface of the chip with the solder pads of the metal traces exposed therefrom.

19. The method for manufacturing a semiconductor package structure as claimed in claim 10, further comprising the following step:
disposing a plurality of solder balls on the solder pads of the metal traces.

20. The method for manufacturing a semiconductor package structure as claimed in claim 10, further comprising the following step:
providing a wafer that defines an active surface and a back surface opposite to the active surface and has a plurality of chips and a plurality of scribe lines formed among the chips, wherein each chip has a plurality of bonding pads and an optical component disposed on the active surface, with the optical component being electrically connected to the chip;
forming a plurality of holes on the active surface of the wafer;
forming a conductive material within the plurality of holes to form a plurality of via holes electrically connected to the bonding pads;
providing a lid and forming a plurality of adhesive ring on the lid;
adhering the lid onto the active surface of the wafer by the adhesive ring so that the adhesive rings respectively surround the optical component on each chip;
forming a plurality of metal traces on the back surface of the wafer, wherein the metal traces are electrically connected to the via holes and define a plurality of solder pads thereon; and
cutting the wafer to form the respective semiconductor package structures.
